(19) United States
(12) Patent Application Publication
(10) Pub. No.: US 2001/0033975 A1
(43) Pub. Date: Oct. 25, 2001

(54) Yield of dies by adding dummy pattern on open area of multi-project mask

(76) Inventors: Wen-Jye Chung, Hisn-Chu (TW); Hsueh-Ling Kuo, Hsin-Chu (TW)

Correspondence Address: Benjamin J. Hauptman, LOWE HAUPTMAN GILMAN & BERNER, LLP, Suite 310, 1700 Diagonal Road, Alexandria, VA, 22314, US

(21) Appl. No.: 09/813,935

(22) Filed: Mar. 22, 2001

Related U.S. Application Data
(63) Continuation-in-part of application No. 09/314,624, filed on May 19, 1999, now abandoned.

(51) Int. Cl. G03F 9/00; G03C 5/00

(52) U.S. Cl. 430/5; 430/30

(57) ABSTRACT

A method of improving yields of dies by adding dummy pattern on open area of multi-project mask is disclosed. Pattern of multi-project mask comprises a main pattern corresponding to a configuration of patterns of different dies and numerous dummy patterns that occupy, even substantially entirely, open area of multi-project mask, where dummy pattern and main pattern are separated by scribing lines. After patterns of multi-project mask are transformed to semiconductor wafer, dies and dummy dies are formed. Obviously, when the semiconductor wafer is treated by some processes such as chemical mechanical polishing and etching, because dies are close to dummy dies then boundaries of dies are protected and then these is no damage on edge of each die.

### BACKGROUND OF THE INVENTION

This application is a continuation-in-part of U.S. patent application Ser. No. 09/314,642, filed May 19, 1999.

1. Field of the Invention

The present invention relates to a method that improves yield of dies, and a more special project of the invention is that dummy patterns are formed on open area of multi-project mask to protect edges of dies which along the open area of wafer.

2. Description of the Prior Art

In standard photolithography process, as shown in FIG. 1A, the pattern of mask is transformed to wafer 10 and then a plurality of fields 12 are formed on wafer 10. Where all fields 12 correspond to same device and each field 12 is separated from other fields 12 by scribing lines 14 with a typical width about 80 to 100 microns. Thus, these fields 12 are dense arranged to take advantage of finite area of wafer 10. In addition, because each field 12 comprises a number of identical devices and each device corresponds to a die, so the size and shape of each die is equal to other dies. In other words, there are several identical dies 16 inside field 12 and identical dies 16 are arranged to take advantage of finite area of field 12 with minimized account of open area, which is the area of wafer 10 that is not occupied by any die. Of course, the arrangement of dies 16 also is the pattern of mask, as shown in FIG. 1B.

After pattern of mask is transformed to wafer 10, wafer 10 is treated by some correlative processes such as etching, depositing, chemical mechanical polishing (CMP). Therefore, an important advantage of dense arrangement is apparent that edges of most dies 16 are protected by adjacent dies 16 so there is no significant damage induced by correlative processes, especially by polishing process. No matter how, because open area of fields 12 is not occupied by pattern of dies 16, some edges of dies 16 are not close to other dies 16 and then there are obvious damages on these edges when wafer 10 is treated by some correlative processes.

Moreover, sometime different devices are formed in a wafer and different dies are combined on a mask. For example, during pilot run period of semiconductor device, only a few samples are required for verifying the function, and then it is wasteful to consume a mask for so few samples. Thus, it is ordinary that samples of different semiconductor devices are consolidated and then multi-project mask is used to form samples of different semiconductor devices on a multi-project wafer. In other words, the pilot runs of different devices only require a multi-project mask to form different devices in a wafer and then pilot run cost is decreased. Of course, when required account of semiconductor devices is small, multi-project mask also is useful to form few dies of different semiconductor devices on a multi-project wafer. However, the main application of multi-project mask is reducing cost of pilot run. Obviously, each pattern of die has a specific size and a specific shape and then there is open area in the multi-project mask. Thus, after all patterns of multi-project mask are transformed to a wafer, edges of some dies that along the open area of field are damaged by following semiconductor process such as etching and chemical mechanical polishing (CMP). Then some disadvantageous such as deterioration and uniformity are appeared in these edges of dies that along the open area of field, and yield of dies are decreased.

According to previous discussion, it is obvious that during correlative semiconductor process of dies, the open area on the multi-project wafer will induce damage on edge of dies that along the open area. In other words, yield of dies of multi-project wafer is an unsolved problem.

### SUMMARY OF THE INVENTION

In accordance with the present invention, a method of improving yield of dies by adding dummy pattern on open area of multi-project mask is disclosed. The method substantially improves the problem that open area on a multi-project mask will induce damages on edges of dies which along the open area.

The spirit of the invention is covering open area of multi-project mask by dummy patterns, and then dummy dies are formed on the open area of field by photolithography process. Moreover, each dummy pattern is not contacted with pattern or other dummy patterns. Thus, all edges of dies are protected by adjacent dies during correlative processes such as etching, deposition, chemical mechanical polishing, no matter these dies correspond to devices or only are dummy dies.

In one provided embodiment, the method is used to improve yield of dies by adding dummy pattern on open area of multi-project mask. First, providing a semiconductor wafer that comprises oxide layer, dielectric layer or numerous semiconductor structures such as gates, electrodes. Second, using a photolithography process to transform pattern of multi-project mask to the semiconductor wafer and then numerous fields are formed. Moreover, pattern of multi-project mask comprises a main pattern that comprises numerous different patterns of dies and each pattern of die has a specific shape and area, pattern of multi-project mask also comprises numerous dummy patterns that cover the open area. Thus, there are both dies and dummy dies on the semiconductor wafer, where dies correspond to different devices and dummy dies just cover the open area of semiconductor wafer. Finally, treat semiconductor wafer by semiconductor process such as chemical mechanical polishing process. Obviously, because the open area is covered by dummy dies and then each edge of die is either adjacent to other die or adjacent to dummy die. Thus, CMP process induces no damage on the edge of die which along the open area and then yield of dies is improved.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A shows conventional configuration of wafer;

FIG. 1B shows conventional configuration of mask with a plurality of identical patterns of dies;

FIG. 2A shows a configuration of multi-project wafer in accordance with one embodiment of the present invention;

FIG. 2B to FIG. 2C show how dummy patter is employed to changer pattern of multi-project mask in accordance with one embodiment of the present invention; and

FIG. 3A to FIG. 3D show how chemical mechanical polishing uniformity of die which along the open area is improved by dummy pattern.

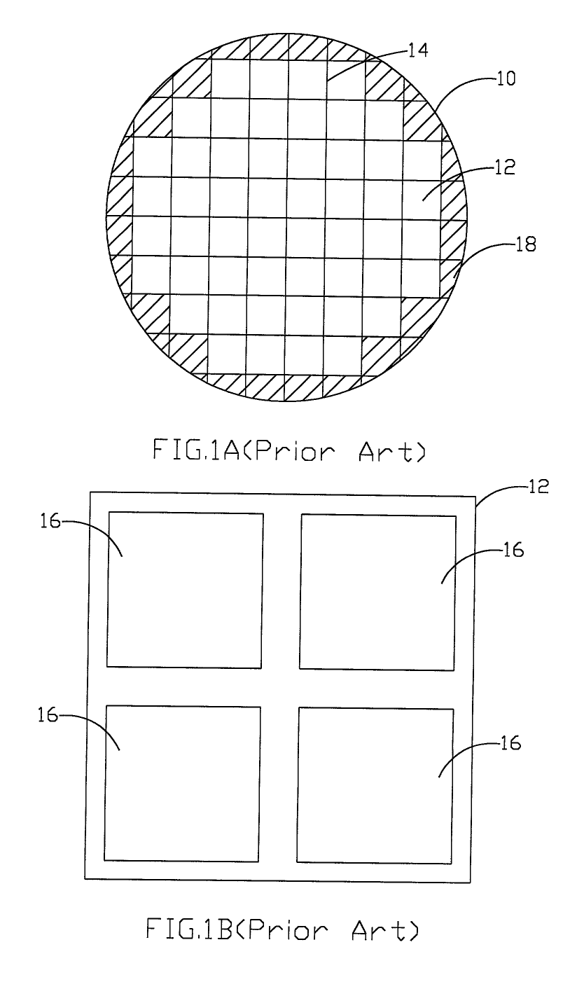

### DESCRIPTION OF THE PREFERRED EMBODIMENT

According to the invention, a method that improves yield of dies by adding dummy pattern on open area of multi-project mask is disclosed. The method comprises following essential concepts: First, when several patterns of dies, same dies or different dies, are formed on a multi-project mask, there are a main pattern an open area on the multi-project mask. Second, dummy patterns are formed on the open area. By the way, after photolithography process, there are dummy dies and then edges of dies are protected by dummy dies during following process. Moreover, dummy patterns could further occupy substantially entirely open area, dummy patterns also could not further occupy substantially entirely open area but are closed to main pattern.

First step, provide semiconductor wafer 20 that comprises oxide layer, dielectric layer or numerous semiconductor structures such as gates, electrodes. In addition, semiconductor wafer 20 is a multi-project wafer (MPW) that a number of different devices will be formed on semiconductor wafer 20.

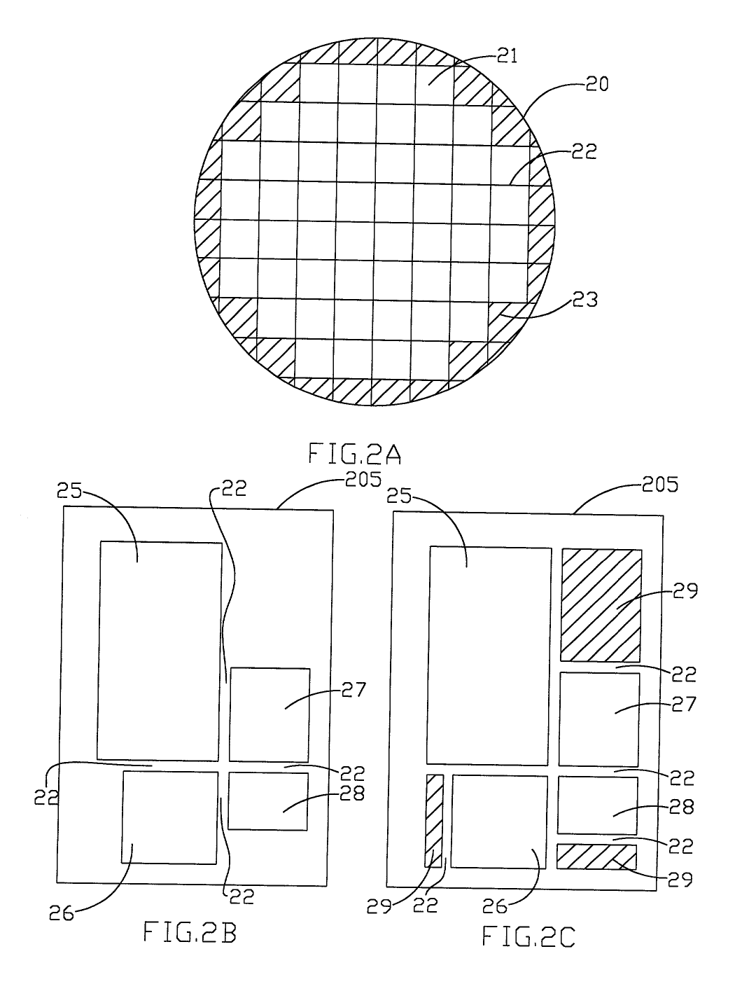

Second step, perform a photolithography process to transform all patterns of multi-project mask 205 to semiconductor wafer 20, where patterns of multi-project mask 205 have a main pattern corresponding to numerous different dies, and having a dummy pattern 29 that occupy open area of multi-project mask 205. By photolithography process, patterns of multi-project mask 205 are transformed to semiconductor wafer 20 and numerous fields 21 are formed, as shown in FIG. 2A. Beside, all fields 21 have an identical pattern as the pattern of multi-project mask 205, and each field 21 is separated to other fields 21 by scribing lines 22 where width of each scribing lines 22 is about 80 to 100 microns. Obviously, fields 21 are densely arranged to exploit finite area of wafer 20 and wafer open area of wafer 20 is effectively decreased. In fact, except scribing lines 22 and edge of multi-project mask 205, these is almost no open area.

Moreover, one character of multi-project mask 205 is that numerous patterns of different devices are combined on a mask. Thus, each field 21 comprises some different dies and each die corresponds to a specific device, and then size and shape of each die also is specified. Obviously, multi-project mask 205 is more useful and economical in pilot run because that required number of each device is few and then different devices may be formed on a wafer to reduce cost of pilot run.

However, as shown in FIG. 2B, main pattern of multi-project mask 205 comprises several different patterns of dies 25, 26,27, 28, and scribing lines 22 also are used to separate different patterns of dies 25, 26,27, 28. Furthermore, each pattern of die 25, 26,27, 28 corresponds to a specific device and has a specific shape and a specific size. Of course, the only restriction of number of different patterns of dies 25, 26,27, 28 is the area of multi-project mask 205 and area of each pattern of die 25, 26,27, 28. Obviously, because size and shape of each pattern of die 25, 26,27, 28 is different to other pattern of die 25, 26,27, 28, open area always exists on multi-project mask 205, where open area indicates the area of multi-project mask 205 which is not occupied by main pattern.

No matter how, because both main pattern and dummy patterns 29 locate on multi-project mask 205, as shown in FIG. 2C, it is obvious that the open area is covered by dummy patterns 29. Where dummy patterns 29 contain no specific image corresponding to any device. Beside, each of dummy patterns 29 also is separated to main pattern and other dummy patterns 29 by scribing lines 22.

Moreover, photolithography process is sued to transform both main pattern and dummy patterns to wafer 20, and then numerous dies and numerous dummy dies 29 are formed on wafer 20, wherein scribing lines of mask also are transformed into wafer 20. It should be emphasized that the width of scribing lines of wafer must match two restrictions. One restriction is the width should be as narrow as possible to prevent polishing damage in edge of dies, and another restriction is that the width should be wide enough to prevent damage during separating adjacent dies and dummy patterns. In general, typical width of scribing lines of wafer is about 80 to 100 microns.

Third step, after photolithography process, the surface of semiconductor wafer 20 is treated by some semiconductor process such as etching process and chemical mechanical polishing process, and these edges of dies that along the open area are protected by dummy dies. The mechanism of protection is explained in following paragraphs.

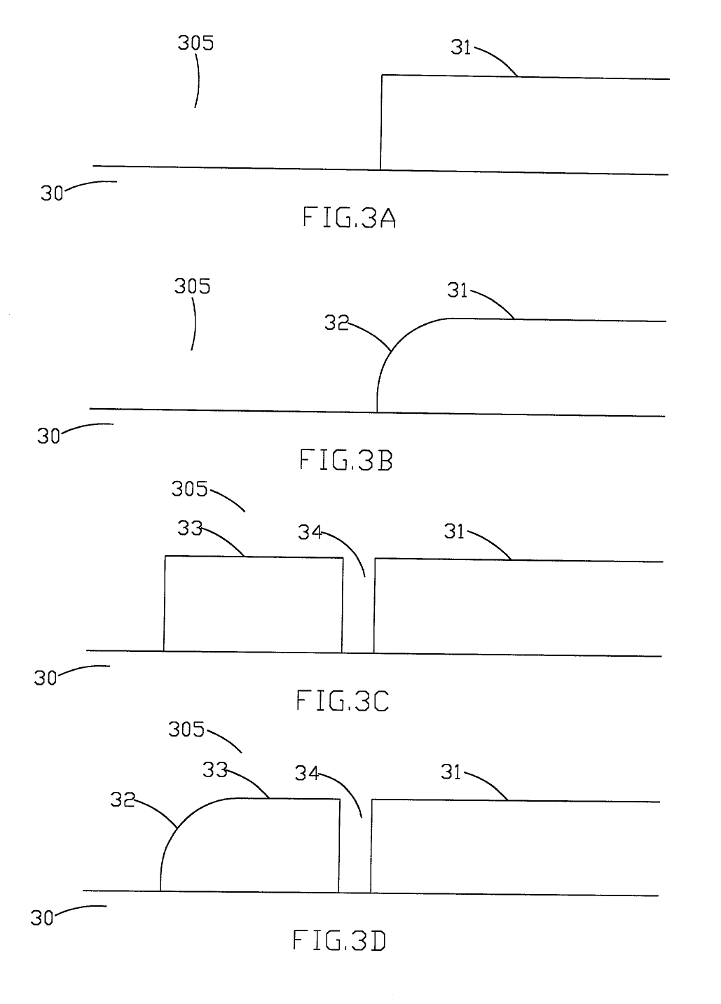

As shown in FIG. 3A, die 31 is formed on wafer 30 and is close to open area 305. Because chemical mechanical polishing process comprises both chemical reaction and mechanical reaction, and the surface of die 31 is polished by pad. It is obvious that the interacting probability between die 31 and pad is higher in edge of die 31 and is highest in corner of edge of die 31. Thus, during polishing process, there is polishing damage in the edge of die 31 that along the open area, as shown in FIG. 3B and it is a main disadvantage of multi-project wafer.

In comparison, as shown in FIG. 3C, when open area of multi-project mask 205 is covered by dummy pattern, open area 305 of wafer 30 is covered by dummy dies 33. Moreover, the separation between die 31 and dummy dies 33 is only scribing line 34 and width of scribing line 34 should balance two restrictions and a typical width of scribing line is about 80 to 100 microns. One restriction is that the width should be minimized to reduce polishing damage on edge of die 31. Another restriction is the width should be enough wide to avoid damage during separating die 31 and dummy die 33. Indisputably, the polishing probability is almost uniform over die 31 and main polishing damage only appears on edge of dummy die 33, as FIG. 3D shows. In other words, the chemical mechanical polishing uniformity of die 31 is improved and then yield of die 31 is improved.

Emphasized that although the provided discussion only discusses how CMP uniformity is improved by the proposed invention. Dummy die 33 on the open area also can protect edge of die 31 which along the open area in other correlative semiconductor process such as etching process. Hence, the distribution of reacting probability is almost uniform over die 31 and these damages that induced by correlative semiconductor process is concentrated in edge of dummy die 33. In other words, no matter which semiconductor process is employed the proposed invention is an effective way to protect edge of die 31 and improve yield of die 31.

Besides, because both FIG. 3A through FIG. 3D and corresponding discussions show that dummy dies 33 protect die 31 by preventing edge of die 31 to be bared, it is reasonable that dummy dies is not desired to cover all open area 305 but only is desired to be close to die 30 to prevent die 31 is bared. In other words, dummy patterns 29 that locate on open area of multi-project mask 205 only is desired to be close to all main patterns 25, 26, 27, and 28.

However, because dummy die 33 is damaged during performed processes, it is reasonable that die 31 would be damaged while dummy die 33 is seriously damaged or consumed. Thus, to properly protect all main dies, it is better to let dummy dies substantially entirely cover all open area 305. In other words, it is better to let dummy patterns 29 occupy substantially entirely all open area of multi-project mask 205.

Furthermore, the embodiment could further comprises a step of forming dummy field 23 on edge of semiconductor wafer 20, where dummy field means that no any die that corresponds to semiconductor device locates in the dummy field. Similarly, the embodiment also could further comprises a step of forming a dummy field pattern on edge of the multi-project mask, wherein the dummy field pattern means that no any pattern that corresponds to any semiconductor device locates in the dummy field pattern. By application of dummy field(s), not only all dies along open area of each field 21 is protected by dummy die 29, but also these dies 21 that along the edge of the semiconductor wafer 20 are protected by dummy field 23.

Although specific embodiments have been illustrated and described, it will be obvious to those skilled in the art that various modifications may be made without departing from what is intended to be limited solely by the appended claims.

What is claimed is:

1. A method of improving yield of dies by adding dummy pattern on an open area of a multi-project mask, said method comprising following steps:
providing a semiconductor wafer;
transforming a pattern of said multi-project mask to said semiconductor wafer by a photolithography process, said pattern having a main pattern corresponding to a plurality of patterns of different dies, and having a plurality of dummy patterns that occupy substantially entirely said open area of said multi-project mask; and
treating said semiconductor wafer by a plurality of semiconductor processes, said semiconductor processes comprising a chemical mechanical polishing process and an etching process.

2. The method according to claim 1, wherein said patterns of different dies have different pattern sizes and different shapes, and said different dies correspond to different devices.

3. The method according to claim 1, wherein said open area comprises an area of said multi-project mask which is not occupied by said main pattern.

4. The method according to claim 1, wherein said dummy patterns contain no specific image corresponding to any device.

5. The method according to claim 1, wherein each said dummy pattern and of each said patterns of different die are separated from each other by a plurality of scribing lines.

6. The method according to claim 5, wherein width of each said scribing line is about 80 to 100 microns.

7. The method according to claim 1, further comprising a step of forming at least a dummy field on edge of said semiconductor wafer, said dummy field contains no die that corresponds to any semiconductor device.

8. A multi-project mask for improving yield of dies by adding dummy pattern on an open area of said multi-project mask, said multi-project mask comprising:
a main pattern corresponding to a plurality of patterns of different dies; and
a plurality of dummy patterns occupying said open area of said multi-project mask.

9. The multi-project mask according to claim 1, wherein said dummy patterns occupy substantially entirely said open area.

10. The multi-project mask according to claim 1, wherein said dummy patterns are close to said main pattern.

11. The multi-project mask according to claim 8, wherein said patterns of different dies have different pattern sizes and different shapes, and said different dies correspond to different devices.

12. The multi-project mask according to claim 8, wherein said open area comprises an area of said multi-project mask which is not occupied by said main pattern.

13. The multi-project mask according to claim 8, wherein said dummy patterns contain no specific image corresponding to any device.

14. The multi-project mask according to claim 10, wherein each of said dummy pattern and each of said patterns of different dies are separated from each other by a plurality of scribing lines.

15. The multi-project mask according to claim 8, further comprising at least a dummy field pattern on edges of said multi-project mask, said dummy field pattern contains no pattern that corresponds to any semiconductor device.

16. A method of improving yield of dies by adding dummy pattern on an open area of a multi-project mask, said method comprising following steps:
providing a semiconductor wafer;
transforming a pattern of said multi-project mask to said semiconductor wafer by a photolithography process, said pattern having a main pattern corresponding to a plurality of patterns of different dies, and having a plurality of dummy patterns that locate on said open area of said multi-project mask and are close to said main pattern; and
treating said semiconductor wafer by a plurality of semiconductor processes, said semiconductor processes comprising a chemical mechanical polishing process and an etching process.

17. The method according to claim 16, wherein said patterns of different dies have different pattern sizes and different shapes, and said different dies correspond to different devices.

18. The method according to claim 16, wherein said open area comprises an area of said multi-project mask which is not occupied by said main pattern.

19. The method according to claim 16, wherein said dummy patterns contain no specific image corresponding to any device.

20. The method according to claim 16, wherein each said dummy pattern and of each said patterns of different die are separated from each other by a plurality of scribing lines.
